(19) United States
(12) Patent Application Publication
(10) Pub. No.: US 2017/0170370 A1
(43) Pub. Date: Jun. 15, 2017

(54) WHITE LIGHT EMITTING DEVICE AND DISPLAY APPARATUS

(71) Applicant: SAMSUNG ELECTRONICS CO., LTD., Suwon-si (KR)

(72) Inventors: Woo Jung PARK, Hwaseong-si (KR); Tae Young CHOI, Seoul (KR)

(73) Assignee: SAMSUNG ELECTRONICS CO., LTD., Suwon-si (KR)

(21) Appl. No.: 15/244,488

(22) Filed: Aug. 23, 2016

(30) Foreign Application Priority Data
Dec. 11, 2015 (KR) 10-2015-0177188

(51) Int. Cl. H01L 33/50; G02F 1/133; G02F 1/1368; G02F 1/1343; F21V 8/00; G02F 1/1335

(52) U.S. Cl. CPC H01L 33/504; G02B 6/0026; G02F 1/133514; G02F 1/1368; G02F 1/134336; G02F 1/13306; G02F 2201/123; G02F 2201/121

(57) ABSTRACT

A white light emitting device includes a blue light emitting diode (LED) configured to emit light having a dominant wavelength in a range of 440 nm to 450 nm; a green phosphor configured to convert at least a first portion of the light emitted by the blue LED to light having a peak wavelength in a range of 510 nm to 535 nm and having a full width at a half maximum of 35 nm or less; and a red phosphor configured to convert at least a second portion of the light emitted by the blue LED to light having a peak wavelength in a range of 610 nm to 635 nm and having a full width at a half maximum of 30 nm or less.

### CROSS-REFERENCE TO RELATED APPLICATION(S)

This application claims priority from Korean Patent Application No. 10-2015-0177188, filed on Dec. 11, 2015, in the Korean Intellectual Property Office, the disclosure of which is incorporated herein in its entirety by reference.

### BACKGROUND

Apparatuses consistent with exemplary embodiments relate to a white light emitting device and a display apparatus.

White light emitting devices are manufactured through a method of combining a blue light emitting diode (LED) with a yellow phosphor, or combining a blue LED with a red phosphor and a green phosphor. As a new color standard of an ultra high definition (UHD) television (TV), BT.2020, has been applied, a color gamut has been expanded to nearly twice the level of the national television systems committee (NTSC) standard, which is a high definition television (HDTV) standard. Accordingly, there has been a problem in that a related art white light emitting device does not implement a sufficient color reproduction range (or color gamut), which is substantially only 70% based on BT.2020.

### SUMMARY

One or more example embodiments provide a white light emitting device and a display apparatus which may implement a relatively high color reproduction range by combining a blue light emitting diode (LED) with a phosphor having a relatively narrow full width at half maximum.

According to an aspect of an example embodiment, provided is a white light emitting device including: a blue light emitting diode (LED) configured to emit light having a dominant wavelength in a range of 440 nm to 450 nm; a green phosphor configured to convert at least a first portion of the light emitted by the blue LED to light having a peak wavelength in a range of 510 nm to 535 nm and having a full width at a half maximum of 35 nm or less; and a red phosphor configured to convert at least a second portion of the light emitted by the blue LED to light having a peak wavelength in a range of 610 nm to 635 nm and having a full width at a half maximum of 30 nm or less.

According to an aspect of another example embodiment, provided is a display apparatus including: an image display panel including a color filter layer, the color filter layer including red, green, and blue color filters; a light source unit including a plurality of blue light emitting diodes (LEDs) that emit light; and a wavelength conversion member including: a green phosphor configured to convert at least a first portion of light emitted by a blue LED to light having a peak wavelength in a range of 510 nm to 535 nm and having a full width at a half maximum of 35 nm or less, and a red phosphor configured to convert at least a second portion of the light emitted by the blue LED to light having a peak wavelength in a range of 610 nm to 635 nm and having a full width at a half maximum of 30 nm or less.

According to an aspect of still another example embodiment, provided is a white light emitting device including: a blue light emitting diode (LED) configured to emit light having a dominant wavelength in a range of 440 nm to 450 nm; a wavelength-conversion member configured to convert at least a portion of light emitted from the blue LED into red light, the wavelength-conversion member including a fluoride phosphor represented by at least one from: a formula AₓMF_{y}:Mn⁴⁺, where A is at least one selected from Li, Na, K, Rb, and Cs, M is at least one selected from Si, Ti, Zr, Hf, Ge, and Sn, and 2≦x≦3 and 4≦y≦7, a formula SrₓMg_{y}Si_{z}N_{2/3(x+y+2z+w)}:Eu_{w}, where 0.5≦x≦2, 2.5≦y≦3.5, 0.5≦z≦1.5, and 0<w≦0.1, and a formula M[LiₓAl_{y}N_{z}]:Eu_{2+W}, where M is at least one selected from Ca, Sr, Ba, Eu, and Mg and 0.1≦x≦1.2, 0.1≦y≦3.5, 0.1≦z≦4.5, and 0<w≦0.1; and a second wavelength-conversion member configured to convert at least a second portion of the light emitted from the blue LED into green light, wherein the green light converted by the second wavelength-conversion member has a peak wavelength in a range of 510 nm to 535 nm and has a full width at a half maximum of 35 nm or less.

### BRIEF DESCRIPTION OF DRAWINGS

The above and/or other aspects will be more apparent by describing certain example embodiments with reference to the accompanying drawings, in which:

FIG. 1 is a schematic cross-sectional view of a white light emitting device according to an example embodiment;

FIG. 2 is a photoluminescence excitation (PLE) spectrum of a green phosphor, employable in an example embodiment;

FIG. 3 is a photoluminescence (PL) spectrum of a green phosphor, employable in an example embodiment;

FIG. 4 is an emission spectrum of a red phosphor, employable in an example embodiment;

FIG. 5 is an emission spectrum of a white light emitting device according to an example embodiment;

FIG. 6 is a CIE 1931 color space chromaticity diagram illustrating color reproducibility of a white light emitting device according to an example embodiment;

FIG. 7 is an emission spectrum of a green phosphor, employable in an example embodiment;

FIG. 8 is a schematic, partially cutaway perspective view of a fluoride phosphor particle according to an example embodiment;

FIG. 9 is a flowchart illustrating a method of manufacturing a fluoride phosphor according to an example embodiment;

FIG. 10 is a schematic, partially cutaway perspective view of a fluoride phosphor particle according to an example embodiment;

FIG. 11 is a schematic cross-sectional view of a white light emitting device according to an example embodiment;

FIGS. 12 and 13 are schematic cross-sectional views of a white light source module according to example embodiments;

FIGS. 14 through 17 are schematic cross-sectional views of backlight units according to example embodiments; and

FIG. 18 is a schematic exploded perspective view of a display apparatus according to an example embodiment.

### DETAILED DESCRIPTION

Hereinafter, certain example embodiments will be described as follows with reference to the attached drawings.

The disclosure may, however, be exemplified in many different forms and should not be construed as being limited to the example embodiments set forth herein. Rather, these embodiments are provided so that this disclosure will be thorough and complete, and will fully convey the scope of the disclosure to those skilled in the art.

Throughout the specification, it will be understood that when an element, such as a layer, region or wafer (substrate), is referred to as being “on,” “connected to,” or “coupled to” another element, it can be directly “on,” “connected to,” or “coupled to” the other element or other elements intervening therebetween may be present. In contrast, when an element is referred to as being “directly on,” “directly connected to,” or “directly coupled to” another element, there may be no elements or layers intervening therebetween. Like numerals refer to like elements throughout. As used herein, the term “and/or” includes any and all combinations of one or more of the associated listed items.

It will be apparent that though the terms first, second, third, etc. may be used herein to describe various members, components, regions, layers and/or sections, these members, components, regions, layers and/or sections should not be limited by these terms. These terms are only used to distinguish one member, component, region, layer or section from another region, layer or section. Thus, a first member, component, region, layer or section discussed below could be termed a second member, component, region, layer or section without departing from the teachings of the exemplary embodiments.

Spatially relative terms, such as “above,” “upper,” “below,” and “lower” and the like, may be used herein for ease of description to describe one element's relationship to another element(s) as shown in the figures. It will be understood that the spatially relative terms are intended to encompass different orientations of the device in use or operation in addition to the orientation depicted in the figures. For example, if the device in the figures is turned over, elements described as “above,” or “upper” other elements would then be oriented “below,” or “lower” the other elements or features. Thus, the term “above” can encompass both the above and below orientations depending on a particular direction of the figures. The device may be otherwise oriented (rotated 90 degrees or at other orientations) and the spatially relative descriptors used herein may be interpreted accordingly.

The terminology used herein describes particular embodiments only, and the disclosure is not limited thereby. As used herein, the singular forms “a,” “an,” and “the” are intended to include the plural forms as well, unless the context clearly indicates otherwise. It will be further understood that the terms “comprises,” and/or “comprising” when used in this specification, specify the presence of stated features, integers, steps, operations, members, elements, and/or groups thereof, but do not preclude the presence or addition of one or more other features, integers, steps, operations, members, elements, and/or groups thereof.

In the drawings, for example, due to manufacturing techniques and/or tolerances, modifications of the shape shown may be estimated. Thus, example embodiments should not be construed as being limited to the particular shapes of regions shown herein, for example, to include a change in shape results in manufacturing. The following embodiments may also be constituted by one or a combination thereof.

The contents of the disclosure described below may have a variety of configurations and propose only example configurations herein, but are not limited thereto.

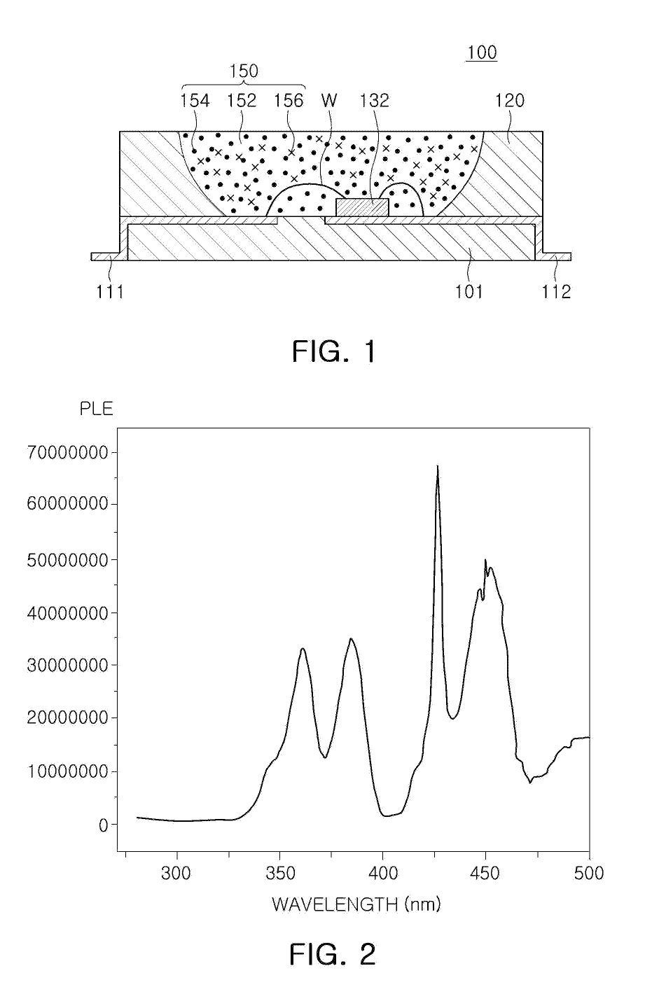

FIG. 1 is a schematic cross-sectional view of a white light emitting device according to an example embodiment.

With reference to FIG. 1, a white light emitting device 100 may include a substrate 101, a blue light emitting diode (LED) 132 disposed on the substrate 101, and a wavelength conversion member 150. The white light emitting device 100 may include a pair of lead frames 111 and 112, electrically connected to the blue LED 132, and a sidewall reflector 120. For example, the sidewall reflector 120 may have a cup-shaped form.

The blue LED 132 may be disposed on an upper surface of the substrate 101, and may include an epitaxially grown semiconductor layer. The blue LED 132 may emit light having a dominant wavelength in a range of 440 nm to 450 nm.

The wavelength conversion member 150 may be disposed in a cavity surrounded by the sidewall reflector 120. The wavelength conversion member 150 may include an encapsulation layer 152, a green phosphor 154, and a red phosphor 156. The green phosphor 154 and the red phosphor 156 may be dispersed in the encapsulation layer 152 and disposed on a path of light emitted by the blue LED 132, and may convert a wavelength of at least a portion of light emitted by the blue LED 132.

In an example embodiment, when the green phosphor 154 is excited by light emitted by the blue LED 132, the green phosphor 154 may generate an emission spectrum having a peak wavelength in a range of 510 nm to 535 nm. In addition, an emission spectrum of the green phosphor 154 may have a full width at half maximum of 35 nm or less. For example, to further improve color reproducibility, the green phosphor 154 may have a peak wavelength in a range of 510 nm to 520 nm.

The green phosphor 154 that satisfies the above conditions of the emission spectrum may include types of phosphors, e.g., oxide, nitride, or oxynitride phosphors such as a barium magnesium aluminate (BAM) phosphor activated by at least one of Mn²⁺ and Eu²⁺. For example, the green phosphor 154 may include at least one from a group consisting of BaMgAl₁₀O₁₇:Mn²⁺, BaMgAl₁₀O₁₇:Eu²⁺,Mn²⁺, BaMg_{1.5}Al_{10.5}O_{18.25}:Eu²⁺,Mn²⁺, BaMg_{1.5}Al_{10.5}O_{18.25}:Eu²⁺, Ba_{0.62}Mg_{0.67}Al_{10.33}O_{18.18}:Eu²⁺Mn²⁺, BaMg₃Al₁₄O₂₁:Em²⁺Mn²⁺, KAlSi₂O₆:Mn²⁺, LaMgAl₁₂O₁₈:Mn²⁺, LaMgAl₁₂O₁₈:Eu²⁺,Mn²⁺, LaAl₁₁O₁₉:Mn²⁺, LaAl₁₁O₁₉:Mn²⁺,Eu²⁺, BA(Eu,Ce,Mg,La)Al₁₁O₁₆N, Ba_{0.95}Al₁₁O_{16.31}N_{0.76}:Eu²⁺,Mn²⁺, MgAl₃N₅:Eu²⁺,Mn²⁺, Mg_{0.2}Al_{1.45}O_{2.15}N_{0.75}:Eu²⁺,Mn²⁺, MgAl₂Si₁₀N₁₄:Eu²⁺,Mn²⁺, Sr₂Al₆O₁₁:Eu²⁺,Mn²⁺, Sr₂MgAl₆O₁₂:Eu²⁺,Mn²⁺, Sr₄Al₁₄O₂₅:Eu²⁺,Mn²⁺, Sr₄Mg₂Al₁₄O₂₇:Eu²⁺,Mn²⁺, Ca₈Mg(SiO₄)₄C₁₂:Eu²⁺,Mn²⁺, and Ca₃SiO₄C₁₂:Eu²⁺,Mn²⁺.

In an example embodiment, when the red phosphor 156 is excited by light emitted by the blue LED 132, the red phosphor 156 may generate an emission spectrum having a peak wavelength in a range of 610 nm to 635 nm. In addition, the emission spectrum of the red phosphor 156 may have a full width at half maximum of 30 nm or less. For example, to further improve color reproducibility, the red phosphor 156 may have a full width at half maximum of 10 nm or less.

The red phosphor 156 that satisfies the above conditions of the emission spectrum may include at least one among phosphors satisfying one of the empirical formulas below.

AₓMF_{y}:Mn⁴⁺, Formula 1)

where A is at least one selected from lithium (Li), sodium (Na), kalium (K), rubidium (Rb), and caesium (Cs), M is at least one selected from silicon (Si), titanium (Ti), zirconium (Zr), hafnium (Hf), germanium (Ge), and tin (Sn), and 2≦x≦3 and 4≦y≦7;

SrₓMg_{y}Si_{z}N_{2/3(x+y+2z+w)}:Eu_{w}, Formula 2)

where 0.5≦x≦2, 2.5≦y≦3.5, 0.5≦z≦1.5, and 0<w≦0.1; and

M[LiₓAl_{y}N_{z}]:Eu_{2+W}, Formula 3)

where M is at least one selected from calcium (Ca), strontium (Sr), barium (Ba), europium (Eu), and magnesium (Mg) and 0.1≦x≦1.2, 0.1≦y≦3.5, 0.1≦z≦4.5, and 0<w≦0.1.

When color obtained by using red, green, and blue color filters is marked by a region in a CIE 1931 color space chromaticity diagram, an area of the region refers to a color reproduction range. A color reproduction range of the white light emitting device 100 that satisfies the conditions described above may be over 80% of a BT.2020 region. Additionally, the color reproduction range of the white light emitting device 100 may be over 100% based on a national television systems committee (NTSC) region. The white light emitting device 100 having the above color reproduction range may implement ultra high definition (UHD) television (TV)-level color.

In an example embodiment, the green phosphor 154 may include at least one selected from phosphors represented by empirical formulas BaMgAl₁₀O₁₇:Eu²⁺, Mn²⁺ and LaMgAl₁₂O₁₈:Mn²⁺, and the red phosphor 156 may include a fluoride phosphor represented by an empirical formula AₓMF_{y}:Mn⁴⁺ satisfying 2≦x≦3 and 4≦y≦7, where A is at least one selected from Li, Na, K, Rb, and Cs, and M is at least one selected from Si, Ti, Zr, Hf, Ge, and Sn.

The encapsulation layer 152 may include a transparent resin such as epoxy, silicone, modified silicone, urethane, oxetane, acryl, polycarbonate, polyimide, or a combination thereof.

The substrate 101 may include a polymer resin with which an injection molding process is easily implemented. For example, the resin may be an opaque resin or a resin including a high-reflectance powder such as an aluminum oxide (Al₂O₃) powder. Additionally, the substrate 101 may include ceramic, and in this case, heat may be easily released. In an example embodiment, the substrate 101 may include a printed circuit board on which a wiring pattern is formed. The sidewall reflector 120 may form an integral package body by being combined with the substrate 101.

The pair of lead frames 111 and 112 may be disposed on the substrate 101 and electrically connected to the blue LED 132 to supply electric power thereto. The lead frames 111 and 112 may be electrically connected to the blue LED 132 by using a wire W. Alternatively, in a case in which the blue LED 132 has a flip-chip structure, the blue LED 132 may be directly connected to the lead frames 111 and 112 by using a conductive bump.

Hereinafter, with reference to example embodiments, a function and effect of a while light emitting device according to example embodiments will be described in more detail.

### Example Embodiment

In an example embodiment, a white light emitting device is manufactured by using an LED chip with light having a 447 nm wavelength as a blue LED and using green and red phosphors represented by BaMgAl₁₀O₁₇:Mn²⁺ and K₂SiF₆:Mn⁴⁺, respectively, and a wavelength conversion member is formed by combining green and red phosphors to obtain white light corresponding to coordinates (0.2815, 0.2484) of the CIE 1931 color space chromaticity diagram.

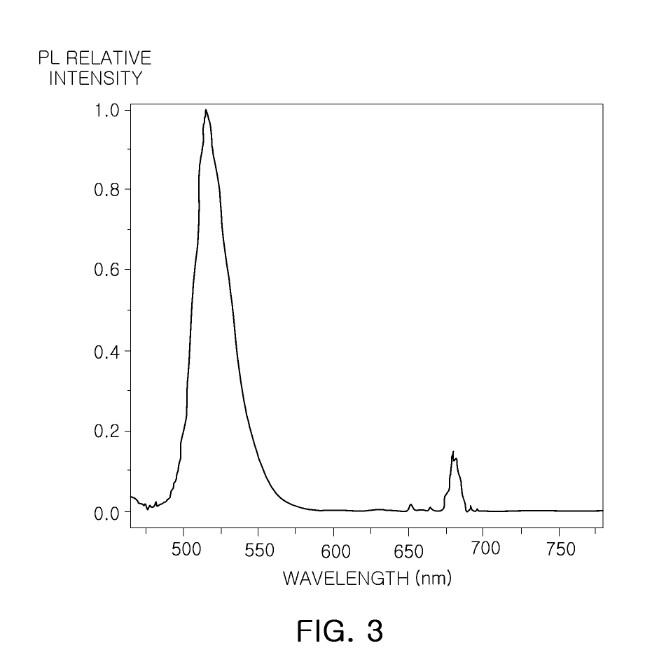

Photoluminescence excitation (PLE) and photoluminescence (PL) spectra of a BaMgAl₁₀O₁₇:Mn²⁺ phosphor, which is a green phosphor, are illustrated in FIGS. 2 and 3, respectively.

With reference to FIG. 2, the BaMgAl₁₀O₁₇:Mn²⁺ phosphor has a first excitation band in a range of 350 nm to 380 nm and a second excitation band in a range of 420 nm to 470 nm. It can be understood that an excitation center is added by introducing Mn²⁺ to BaMgAl₁₀O₁₇ as an activator, which causes addition of the first excitation band. With reference to FIG. 3, an emission spectrum of the BaMgAl₁₀O₁₇:Mn²⁺ phosphor has a narrow full width at half maximum of 27 nm, along with a peak wavelength of 515.5 nm.

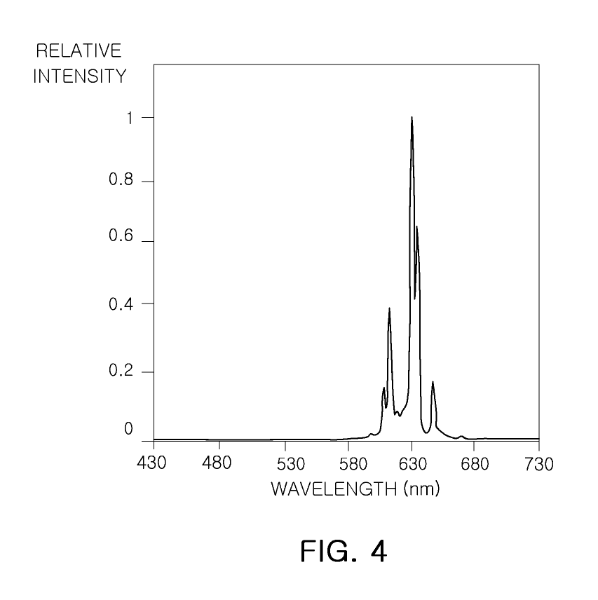

An emission spectrum of a K₂SiF₆:Mn⁴⁺ phosphor, which is a red phosphor, is illustrated in FIG. 4. With reference to FIG. 4, the emission spectrum of the K₂SiF₆:Mn⁴⁺ phosphor has a peak wavelength of 630 nm and a narrow full width at half maximum of 10 nm or less.

Accordingly, conditions of respective green and red phosphors in an example embodiment satisfy the above discussed emission spectrum conditions.

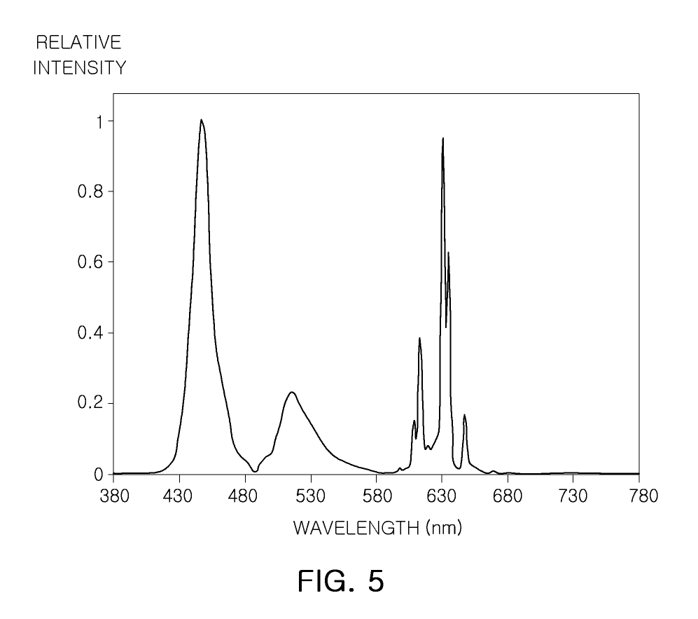

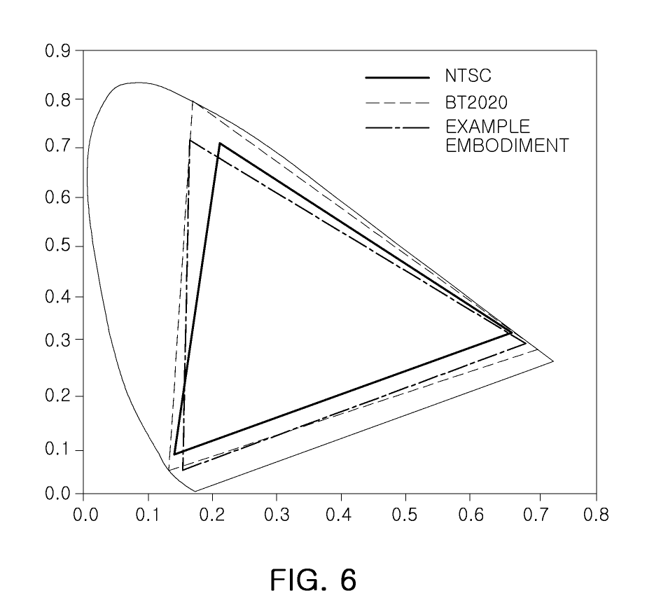

An emission spectrum of the white light emitting device according to an example embodiment, is measured as illustrated in FIG. 5. In addition, color gamuts that may be implemented by using red, green, and blue color filters (e.g., 60 inch model by Sharp Corporation in 2012) are marked in the CIE 1931 color space chromaticity diagram as illustrated in FIG. 6.

With reference to FIG. 6, along with color gamuts that may be implemented in the example embodiment, BT.2020 and NTSC color gamuts are marked by triangles having red, green, and blue vertexes. Color coordinates corresponding to each vertex and color reproduction ranges covered in the example embodiment are shown in Table 1 below.

TABLE 1

| | | | | Color |
|---|---|---|---|---|
| | | | | Reproduction |
| Classification | Red | Green | Blue | Range |
| Example | (0.687, | (0.162, | (0.152, | — |
| Embodiment | 0.304) | 0.717) | 0.049) | |
| BT.2020 | (0.708, | (0.17, | (0.131, | 83.4% |
| | 0.292) | 0.797) | 0.046) | |
| NTSC | (0.67, | (0.21, 0.71) | (0.14, 0.08) | 112% |
| | 0.33) | | | |

As shown in Table 1, the white light emitting device according to an example embodiment represents high color reproduction ranges such as about 83.4% in comparison with the BT.2020 color gamut and about 112% in comparison with the NTSC color gamut.

### Comparative Examples 1 and 2

In Comparative Examples 1 and 2, a white light emitting device is manufactured by providing a wavelength conversion member to obtain white light having CIE 1931 coordinates (0.2815, 0.2484) along with a blue LED chip of 447 nm, while the wavelength conversion member is formed in a manner different from the foregoing example embodiment.

The wavelength conversion member employed in Comparative Example 1 uses the K₂SiF₆:Mn⁴⁺ phosphor the same as that in the foregoing example embodiment as a red phosphor, while β-SiAlON having a peak wavelength of 533 nm is used as a green phosphor. In Comparative Example 2, green and red quantum dots are used as a wavelength conversion material.

In the case of the white light emitting device obtained in Comparative Examples 1 and 2, a color reproduction range measured by using the same color filter as that in the foregoing example embodiment is shown in Table 2 below.

TABLE 2

| | Color Reproduction | Color Reproduction |
|---|---|---|
| | Range (%) | Range (%) |
| | in Comparison | in Comparison |
| Classification | with BT.2020 | with NTSC |
| Example Embodiment | 83.4 | 112 |
| Comparative Example 1 | 72 | 94 |
| Comparative Example 2 | 72 | 95 |

As shown in Table 2, a color reproduction range of a combination of an existing quantum dot and/or phosphor having excellent color reproducibility is only approximately 70% in comparison with BT.2020. On the other hand, according to an example embodiment, a color reproduction range in comparison with BT.2020 may be substantially improved to 80% or more, sufficient to implement a UHD level.

Color reproducibility may be substantially increased by using green and red phosphors that satisfy the above described conditions of a peak wavelength and a full width at half maximum, according to the example embodiment. A different phosphor may be used other than the phosphor used in the foregoing example embodiment as long as the phosphor satisfies the above described conditions.

Green phosphors employable in an example embodiment are illustrated in Table 3 below. Color coordinates, peak wavelengths, and full widths at half maximum are calculated from an emission spectrum when the green phosphors are excited by light having a wavelength of 450 nm as illustrated in Table 3 below.

TABLE 3

| | | | | Full Width |
|---|---|---|---|---|
| | | | Peak | at Half |
| | | | Wavelength | Maximum |
| Classification | CIE x | CIE y | (nm) | (nm) |
| BaMgAl10O17:Mn2+ | 0.1266 | 0.754 | 515.5 | 27 |
| BaMgAl10O17:Eu2+,Mn2+ | 0.1268 | 0.7535 | 516 | 28 |
| BaMgAl10O17:Eu2+,Mn2+ | 0.1531 | 0.7513 | 518 | 27.5 |
| LaMgAl12O18:Mn2+,Eu2+ | 0.1657 | 0.7386 | 516.6 | 28.7 |

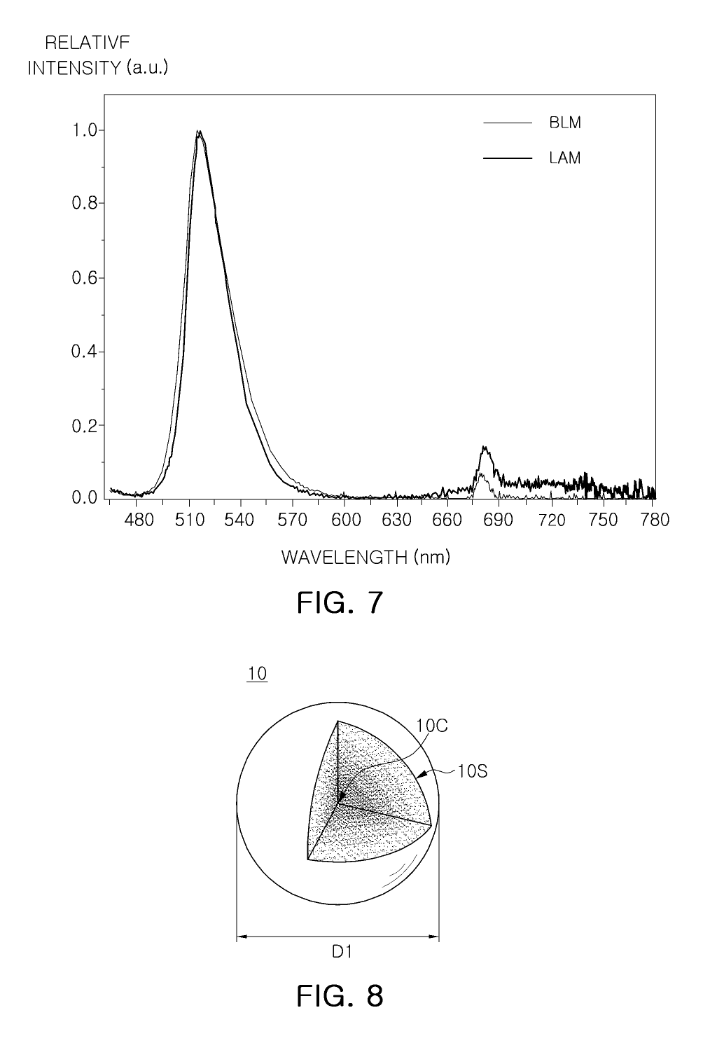

For example, emission spectra of BaMgAl₁₀O₁₇:Eu²⁺,Mn²⁺ (BLM) phosphor and LaMgAl₁₂O₁₈:Mn²⁺,Eu²⁺ (LAM) phosphor among the green phosphors described above are illustrated in FIG. 7. With reference to FIG. 7, it can be confirmed that emission spectra of the BLM and LAM phosphors, for example, profiles of green peak areas, are similar to each other. The BLM and LAM phosphors may be expected to have similar performance when introduced to the white light emitting device according to the example embodiment.

A fluoride phosphor among red phosphors employable in the example embodiment may be used in various forms and/or modifications. With reference to FIGS. 8 to 10, a fluoride phosphor which may be usefully employed in the example embodiment is described.

FIG. 8 is a schematic, partially cutaway perspective view of a fluoride phosphor particle according to an example embodiment.

With reference to FIG. 8, a fluoride phosphor particle 10 according to an example embodiment may include a fluoride having a composition of AₓMF_{y}:Mn⁴⁺, and the empirical formula may satisfy the conditions below.

1) A is at least one selected from Li, Na, K, Rb, and Cs;

2) M is at least one selected from Si, Ti, Zr, Hf, Ge, and Sn;

3) A compositional ratio (x) of A satisfies 2≦x≦3; and

4) A compositional ratio (y) of F satisfies 4≦y≦7.

The fluoride phosphor particle 10 represented by the empirical formula AₓMF_{y}:Mn⁴⁺ may include K₂SiF₆:Mn⁴⁺, K₂TiF₆:Mn⁴⁺, K₂SnF₆:Mn⁴⁺, Na₂TiF₆:Mn⁴⁺, Na₂ZrF₆:Mn⁴⁺, K₃SiF₇: Mn⁴⁺, K₃ZrF₇:Mn⁴⁺, and K₃ SiF₅:Mn⁴⁺. The fluoride phosphor particle 10 may be excited by a wavelength of light between an ultraviolet region to a blue region of the electromagnetic spectrum to emit red light. For example, the fluoride phosphor particle 10 may provide a phosphor that absorbs excitation light having a peak wavelength in a range of 300 nm to 500 nm to emit light having a peak wavelength in a range of 620 nm to 635 nm, as a red phosphor.

The fluoride phosphor particle 10 may have a concentration of Mn⁴⁺, an activator, that is gradually reduced from a center 10C to a surface 10S. The concentration gradually reducing is defined as a concentration which is continuously reduced such that the fluoride phosphor particle 10 does not have a portion of a predetermined thickness or more, in which the concentration is uniformly maintained. For example, the fluoride phosphor particle 10 may not have a uniform concentration of Mn⁴⁺ within a region of which a size exceeds 10% of a particle size D1 in a direction from the center 10C to the surface 10S of the fluoride phosphor particle 10. An average reduction rate of Mn⁴⁺ concentration, for example, in an overall radius of the fluoride phosphor particle 10 may be about 0.4 at. %/μm to about 0.8 at. %/μm. However, the concentration reduction rate, with respect to an overall radius of the fluoride phosphor particle 10, may not be uniform. For example, the reduction rate of Mn⁴⁺ concentration from the center 10C to the surface 10S of the fluoride phosphor particle 10 may be within a range of about 0.1 at. %/μm to about 1.5 at. %/μm according to a region of the fluoride phosphor particle 10.

In addition, the Mn⁴⁺ concentration may be about 3 at. % about to 5 at. % in the center 10C of the fluoride phosphor particle 10, and may be about 1.5 at. % or lower on the surface 10S of the fluoride phosphor particle 10. A difference in Mn⁴⁺ concentrations between the center 10C and the surface 10S of the fluoride phosphor particle 10 may be within a range of about 2 at. % to about 4 at. %. The particle size D1 of the fluoride phosphor particle 10 may be within a range of 5 μm to 25 μm.

Since the fluoride phosphor particle 10 according to an example embodiment has a composition in which the Mn⁴⁺ concentration is reduced from the center 10C toward the surface 10S thereof, the fluoride phosphor particle 10 may be less vulnerable to moisture and may have improved reliability.

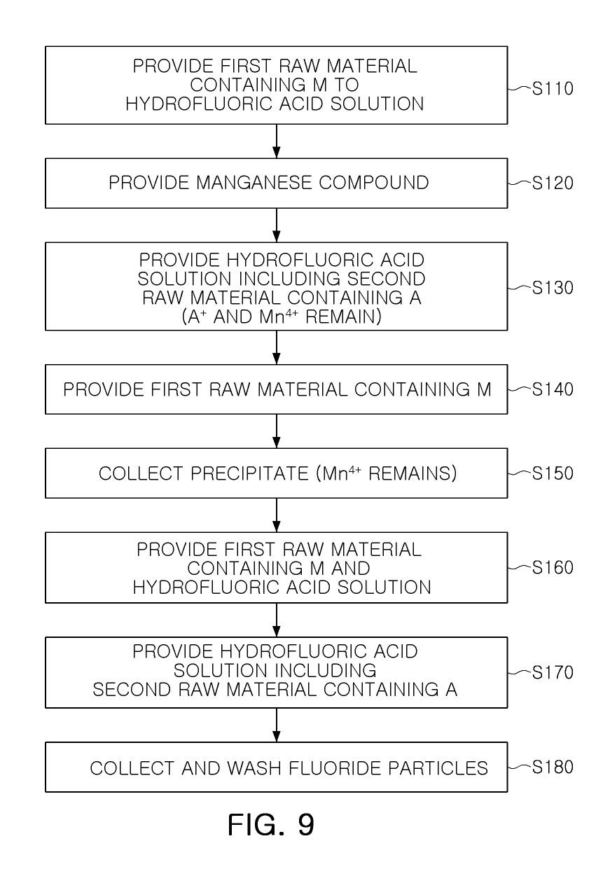

FIG. 9 is a flowchart illustrating a method of manufacturing a fluoride phosphor according to an example embodiment.

With reference to FIG. 9, a method of manufacturing a fluoride phosphor may include providing a first raw material containing M to a hydrofluoric acid solution (S110), providing a manganese compound thereto (S120), providing a hydrofluoric acid solution including a second raw material containing A to a result of operation S120 (S130), providing a first raw material containing M to a result of operation S130 (S140), collecting a formed precipitate from a result of operation S140 (S150), providing a first raw material containing M and a hydrofluoric acid solution to a result of operation S150 (S160), providing a hydrofluoric acid solution including a second raw material containing A to a result of operation S160 (S170), and collecting and washing fluoride particles from a result of operation S170 (S180).

The above operations may be performed at room temperature, but are not limited thereto.

A first raw material containing M may be added to a hydrofluoric acid solution in S110.

The first raw material may be at least one of HₓMF_{y}, AₓMF_{y} and MO₂, and for example, may be H₂SiF₆ or K₂SiF₆. The first raw material may be added to the hydrofluoric acid solution and then stirred for several minutes to appropriately dissolve therein.

Subsequently, a manganese compound may be added to the hydrofluoric acid solution in S120.

Accordingly, a first solution containing the first raw material containing M and the manganese compound may be produced. The manganese compound may be a compound containing Mn⁴⁺, and for example, may have a composition of AₓMnF_{y}. For example, the manganese compound may be K₂MnF₆ by way of example. In a similar manner to that of S110, the manganese compound may be provided to the hydrofluoric acid solution in which the first raw material dissolved and may be stirred to sufficiently dissolve therein.

Although the example embodiment of FIG. 9 illustrates the case in which the first raw material containing M and the manganese compound are sequentially added to the hydrofluoric acid solution, the first solution may be produced in a different order. For example, in another example embodiment, after a manganese compound is first provided to the hydrofluoric acid solution, a first raw material containing M may be provided thereto.

Next, the hydrofluoric acid solution including a second raw material containing A may be provided to the first solution in S130.

In detail, a second solution including a second raw material containing A may be provided to the first solution, to produce a third solution. The second raw material may be AHF₂, for example, KHF₂, and may be in a saturation solution state or powder form.

When the respective raw material concentrations approach a solubility limit of the hydrofluoric acid solution, a precipitate having orange color may be formed. The precipitate may be Mn⁴⁺-activated fluoride (AₓMF_{y}:Mn⁴⁺). For example, when H₂SiF₆ and KHF₂ are used as the first and second raw materials, and K₂MnF₆ is used as a Mn⁴⁺ containing compound, the precipitate may be fluoride represented by K₂SiF₆:Mn⁴⁺.

In S130, A⁺ and Mn⁴⁺ not reacting to the precipitate may remain in the third solution.

In S130, an amount of the second raw material may be accumulatively added to the third solution at an interval corresponding to a reaction time of the second raw material, and thus a particle size of fluoride may be adjusted. An average particle size and particle size distribution may be controlled by adjusting a number of adding the second raw material, an amount of the second raw material being added, and an interval at which the second raw material is added, and the like. For example, when the second raw material is added four times, fluoride seeds may be formed by a firstly added second raw material, and the fluoride seeds may be grown by a secondly and thirdly added second raw material, and precipitation of the grown seeds may be induced by a fourthly added second raw material.

Subsequently, the first raw material containing M may be added to the third solution in S140.

The first raw material may be the same material as the material used in S110, but is not limited thereto. The first raw material may be at least one of HₓMF_{y} and AₓMF_{y}, and for example, may be H₂SiF₆ or K₂SiF₆. The first raw material may be added to the third solution, and then may be stirred for several minutes to appropriately dissolve therein.

In S140, the added first raw material may react with A⁺ and Mn⁴⁺ remaining in the third solution described above to allow the precipitate to grow. Thus, in operation S140, a Mn⁴⁺ concentration in the third solution may be relatively low. For example, in a case in which K₂SiF₆:Mn⁴⁺ is synthesized in S130, when a H₂SiF₆ solution is additionally supplied in S140, the H₂SiF₆ solution reacts with residual KHF₂ and Mn⁴⁺ to generate K₂SiF₆ and to be grown in a shell form on a surface of the fluoride formed in S130.

Although the example embodiment of FIG. 9 illustrates the case in which the second raw material remains after S130, the first raw material may remain after S130. In this case, the second raw material containing A may be provided instead of providing the first raw material in S140.

An amount of the first raw material provided in S140 may be smaller than that of the first raw material provided to the first solution in S110, and for example, a volume of the first raw material provided in S140 may be within a range of 15% to 25% of a volume of the first raw material provided in S110.

Subsequently, the formed precipitate may be collected in S150.

The precipitate may be a precipitate that has begun forming in S130, and Mn⁴⁺ remaining on a surface of the precipitate may also be collected. On the other hand, the second raw material such as A⁺ may be substantially entirely consumed in S140, and thus may not remain in the third solution.

In S150, hydrofluoric acid may be removed, and the precipitate may be collected, and thus Mn⁴⁺ remaining in the hydrofluoric acid solution (or the third solution) may be removed together. Thus, since only a small amount of Mn⁴⁺ remaining on the precipitate surface may be used at the time of a reaction in a subsequent process, a Mn⁴⁺ concentration in a phosphor region that is subsequently grown may be further decreased.

Next, the first raw material containing M and the hydrofluoric acid solution may be added to the precipitate in S160. Thereby, a fourth solution may be produced.

The first raw material may be the same material as the material used in S110 and S140, but is not limited thereto.

An amount of the first raw material provided in S160 may be smaller than that of the first raw material provided to the first solution in S110, and for example, a volume of the first raw material provided in S160 may be within a range equal to 15% to 25% of that of the first raw material provided to the first solution in S110.

Subsequently, the hydrofluoric acid solution including the second raw material containing A may be provided to the fourth solution in S170.

For example, the second solution, a hydrofluoric acid solution including the second raw material containing A, may be re-provided to the fourth solution. The second solution may contain the same second raw material as that used in S130, but is not limited thereto. In S170, a particle size of a fluoride particle to be formed may be controlled by dividing an amount of the second raw material and providing the divided amounts at an interval corresponding to a reaction time thereof.

The amount of the second raw material used in S170 may be smaller than that of the second raw material provided to the first solution in S130, and for example, a weight of the second raw material used in S170 may be within a range equal to about 40% to about 60% of that of the second raw material provided to the first solution in S130.

The second raw material may react with Mn⁴⁺ remaining on the precipitate and the first raw material within the fourth solution and be formed in a shell form on the fluorides of the precipitate in such a manner that fluoride particles are formed. For convenience of explanation and to distinguish from the precipitate formed in S150, a final phosphor particle formed in S170 may be referred to as a fluoride particle. However, a fluoride phosphor according to an example embodiment may include a fluoride material that is grown from the precipitate and is finally formed in S170, and is not limited to a name referred to in respective operations.

Subsequently, fluoride particles may be collected and washed in S180.

The washing process may be performed using a hydrofluoric acid solution and/or an acetone solution as a washing solution. The washing process may be performed by stirring the precipitate using, for example, about 49% of high concentration hydrofluoric acid aqueous solution, and thus, impurities present on the fluoride particles, residual first and second raw materials, and the like may be removed. In an example embodiment, the washing process may also be performed a plurality of times using different cleansing solutions.

Then, a fluoride phosphor according to an example embodiment may be obtained by drying washed fluoride particles. Selectively, the fluoride particles may be dried, and then a heat treatment process thereof at about 100° C. to about 150° C. may further be performed.

The fluoride phosphor in which a content of manganese is gradually reduced from a center portion toward a circumferential portion may be produced through the processes as described above. In the example embodiment, a manganese compound containing Mn⁴⁺ may be provided once in S120, and the number of inputs and an input amount of the first and second raw materials may be adjusted, and thus phosphor particles may be grown in an environment in which a Mn⁴⁺ concentration is continuously reduced.

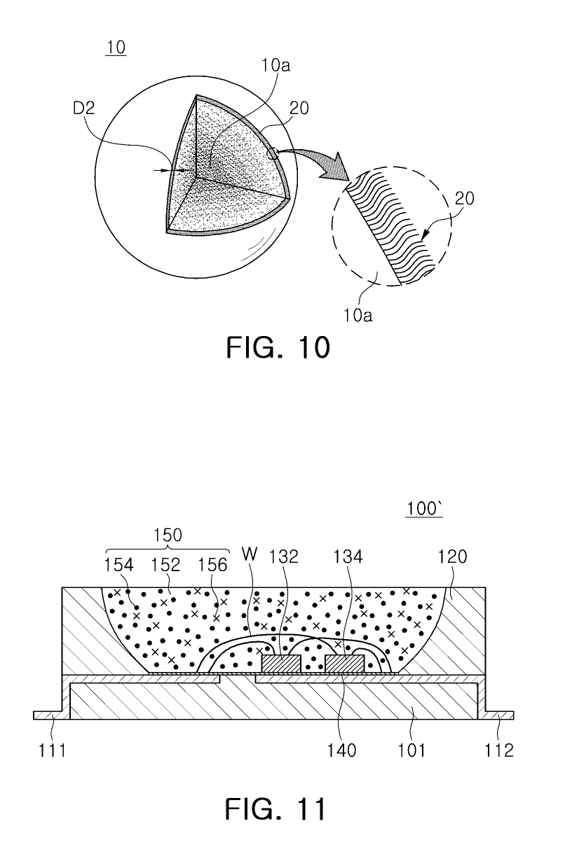

FIG. 10 is a schematic, partially cutaway perspective view of a fluoride phosphor particle according to an example embodiment.

With reference to FIG. 10, a fluoride phosphor particle 10 according to an example embodiment may include a fluoride particle 10a represented by AₓMF_{y}:Mn⁴⁺ and organic materials 20 adsorbed onto a surface of the fluoride particle 10a.

The fluoride particle 10a may be a core of the fluoride phosphor particle 10, and may have the same configuration as the fluoride phosphor particle 10 of the example embodiment of FIG. 1. Thus, the fluoride particle 10a may have a composition in which a concentration of Mn⁴⁺ is gradually reduced from a center thereof to a surface thereof. For instance, the fluoride phosphor particle 10 may have a structure in which the organic materials 20 are added to the fluoride phosphor particle 10 of the example embodiment of FIG. 8.

The organic materials 20 may be physically adsorbed onto a surface of the fluoride particle 10a to protect the fluoride particle 10a. The organic materials 20 may include materials having a hydrophobic tail. Thus, a surface of the fluoride phosphor particle 10 may have hydrophobicity to have further increased moisture resistance.

For example, the organic materials 20 may have at least one functional group between a carboxylic group (—COOH) and an amino group (—NH₂), and may include an organic compound having carbon numbers 4 to 18. For example, the organic materials 20 may include fatty acids, such as an oleic acid having a composition of C₁₈H₃₄O₂. In this case, since a length of one organic material 20 may be several nanometers or less, a thickness D2 of a coating layer by the organic material 20 may also be within a range of several nanometers to tens of nanometers. For example, the thickness D2 of the coating layer may be 5 nm or less.

FIG. 11 is a schematic cross-sectional view of a white light emitting device according to an example embodiment.

With reference to FIG. 11, a white light emitting device 100′ may include a substrate 101, a blue LED 132 and a near ultraviolet LED 134 disposed on the substrate 101, a protective layer 140, and a wavelength conversion member 150.

The white light emitting device 100′ may include a pair of lead frames 111 and 112 electrically connected to the blue LED 132 and the near ultraviolet LED 134, a cup-shaped sidewall reflector 120, and a conductive wire W connecting the blue LED 132 and the near ultraviolet LED 134 with the lead frames 111 and 112.

Compared with the white light emitting device 100 illustrated in FIG. 1, the white light emitting device 100′ illustrated in FIG. 11 may further include the near ultraviolet LED 134. Since a green phosphor 154 employed in the example embodiment forms an excitation band in a near ultraviolet band by introducing Mn and Eu²⁺ as an activator, sufficient green light may be obtained from the green phosphor 154 by further employing the near ultraviolet LED 134. That is, efficiency of the green phosphor 154 may be improved by using the near ultraviolet LED 134 together with the green phosphor 154.

The protective layer 140 may be disposed on at least one surface of the wavelength conversion member 150. In a case in which a fluoride phosphor is used as a red phosphor 156, the protective layer 140 may protect the fluoride phosphor from an external environment, e.g., moisture, and may improve reliability of the white light emitting device 100′. The protective layer 140 may include a moisture resistive material capable of substantially preventing the permeation of moisture.

In the example embodiment of FIG. 11, although the protective layer 140 is disposed on a lower surface of the wavelength conversion member 150, for example, between the wavelength conversion member 150 and the substrate 101, the disposition of the protective layer 140 may be variously changed according to example embodiments. For example, the protective layer 140 may be disposed on both of an upper surface and the lower surface of the wavelength conversion member 150, or may be disposed to encompass the entirety of the wavelength conversion member 150.

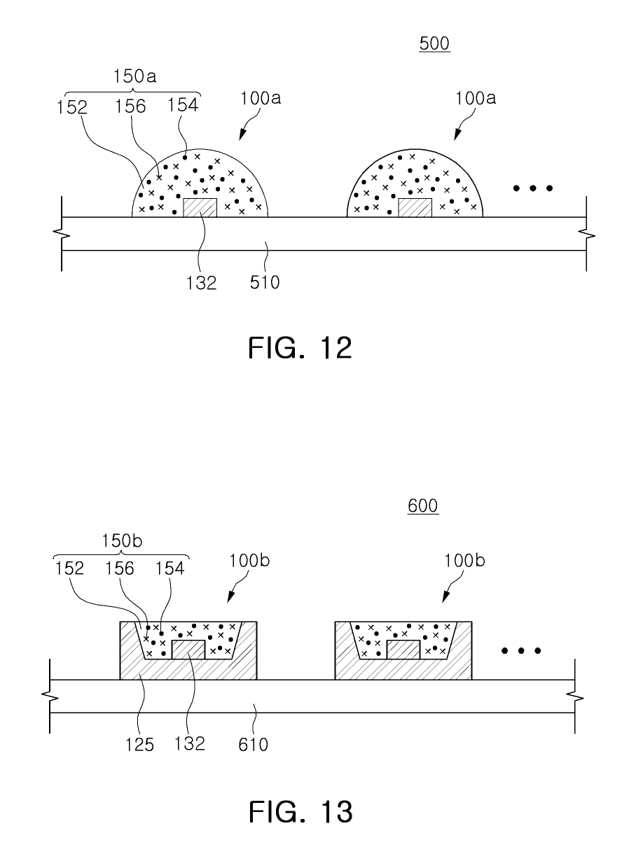

FIGS. 12 and 13 are schematic cross-sectional views of white light source modules according to example embodiments.

With reference to FIG. 12, a light source module 500 to be used in a liquid crystal display (LCD) backlight (or light source) may include a circuit board 510 and a plurality of white light emitting devices 100a mounted on the circuit board 510.

A conductive pattern connected to the white light emitting devices 100a may be formed on the circuit board 510. Each white light emitting device 100a may have a structure in which a blue LED 132 is directly mounted on the circuit board 510 in a chip-on-board (COB) scheme, which is different from the case of the white light emitting device 100 illustrated in FIG. 1. In an example embodiment, the white light emitting devices 100a may not have a separate reflective wall, and the wavelength conversion member 150a may have a semispherical shape having a lens function to exhibit a wide-beam angle. The wide-beam angle of the wavelength conversion member 150a may contribute to a reduction in a thickness or a width of an LCD display. The wavelength conversion member 150a may include an encapsulation layer 152, a green phosphor 154, and a red phosphor 156.

With reference to FIG. 13, a light source module 600 to be used in an LCD backlight may include a circuit board 610 and a plurality of white light emitting devices 100b mounted on the circuit board 610.

Each white light emitting device 100b may include a blue LED 132 mounted in a reflective cup of a package body 125 and a wavelength conversion member 150b encapsulating the blue LED 132. In the wavelength conversion member 150b, a green phosphor 154 and a red phosphor 156 may be distributed. The wavelength conversion member 150b may include an encapsulation layer 152, a green phosphor 154, and a red phosphor 156.

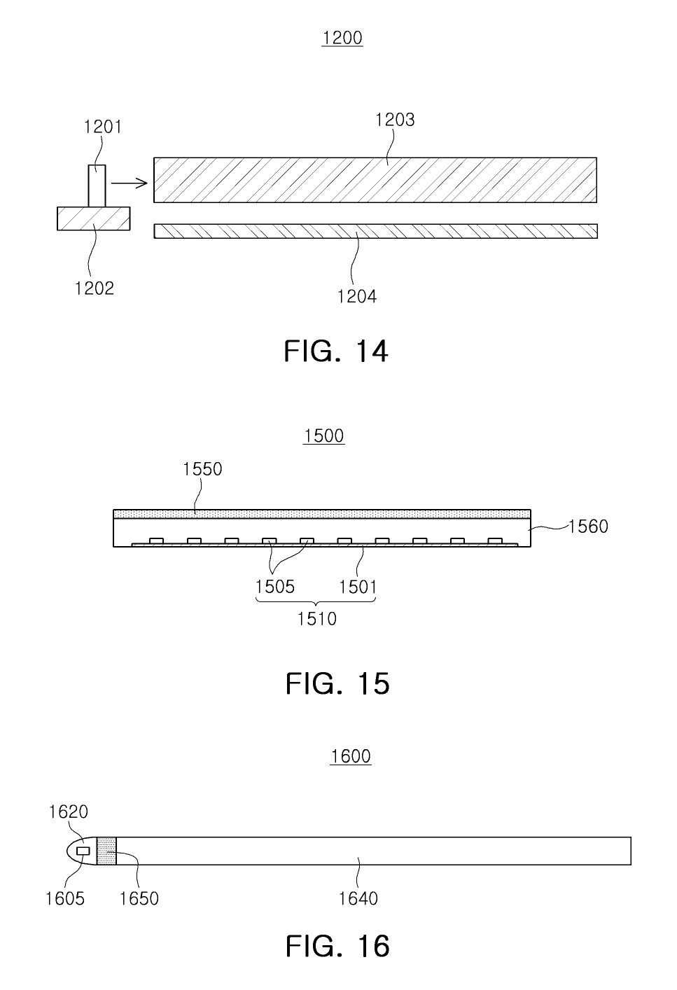

FIGS. 14 through 17 are schematic cross-sectional views of backlight units according to example embodiments.

With reference to FIG. 14, in a backlight unit 1200 according to an example embodiment, a white light emitting device 1201 mounted on a substrate 1202 emits light in a lateral direction in such a manner that the emitted light may be incident onto a light guiding panel 1203 to be converted into a form of surface light source type light. The white light emitting device 1201 employed in the example embodiment may be a white light emitting device according to the foregoing example embodiments. Light passing through the light guiding panel 1203 may be discharged in an upward direction, and a reflective layer 1204 may be disposed below the light guiding panel 1203 to improve light extraction efficiency.

In backlight units 1500, 1600, and 1700, illustrated in FIGS. 15 through 17, the wavelength conversion member that converts light may not be directly disposed in a blue LED 1505, 1605, or 1705. For example, the wavelength conversion member may be disposed at a location, within the backlight unit 1500, 1600, or 1700, that is spaced apart from the blue LED 1505, 1605, or 1705.

With reference to FIG. 15, the backlight unit 1500 may be a direct-type backlight unit and may include a wavelength conversion member 1550, a light source module 1510 arranged below the wavelength conversion member 1550, and a bottom case 1560 that receives the light source module 1510. In addition, the light source module 1510 may include a printed circuit board 1501 and a plurality of blue LEDs 1505 mounted on the printed circuit board 1501.

In the backlight unit 1500 according to the example embodiment, the wavelength conversion member 1550 may be disposed on the bottom case 1560. The wavelength conversion member 1550 may include green and red phosphors in a similar manner to the wavelength conversion units 150, 150a, and 150b according to the foregoing example embodiments. Thus, a wavelength of at least a portion of light emitted by the light source module 1510 may be converted by the wavelength conversion member 1550. The wavelength conversion member 1550 may be manufactured and used as a separate film, or may be provided in a form in which the wavelength conversion member 1550 is integrated with a light diffusion plate (not illustrated).

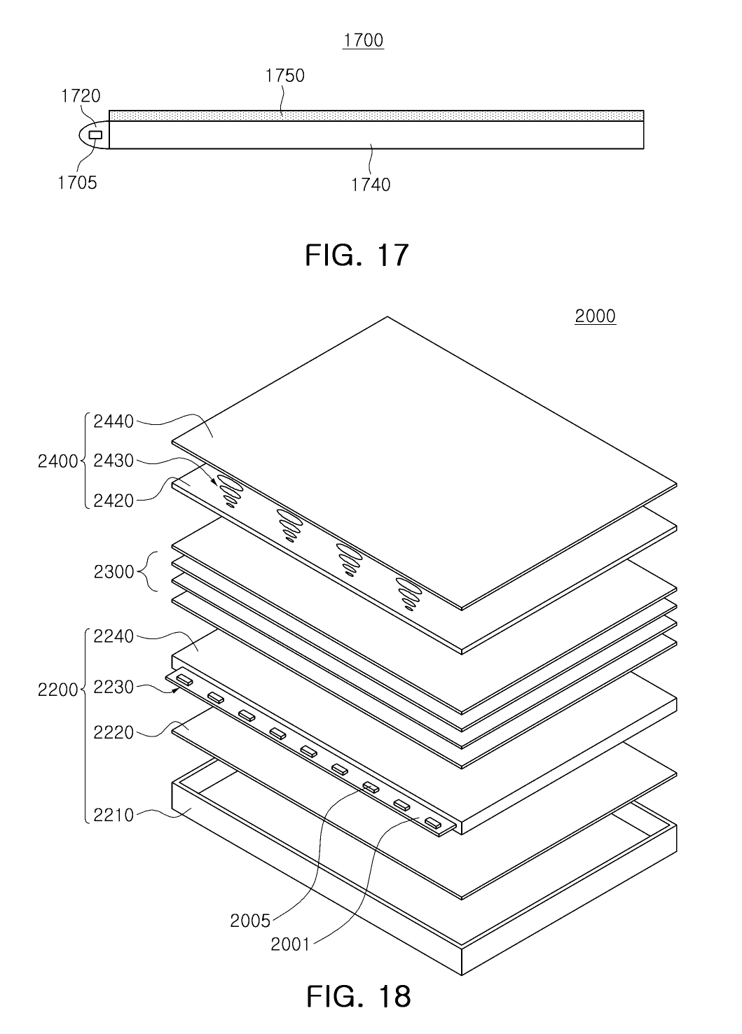

With reference to FIGS. 16 and 17, the backlight unit 1600 or 1700 may be provided as an edge-type backlight unit, and may include a wavelength conversion member 1650 or 1750, a light guiding plate 1640 or 1740, a reflective unit 1620 or 1720 disposed on a side of the light guiding plate 1640 or 1740, and a blue LED 1605 or 1705 as a light source.

Light emitted by the blue LED 1605 or 1705 may be guided to an inner portion of the light guiding plate 1640 or 1740 by the reflective unit 1620 or 1720. In the backlight unit 1600 illustrated in FIG. 16, the wavelength conversion member 1650 may be disposed between the light guiding plate 1640 and the blue LED 1605.

In the backlight unit 1700 illustrated in FIG. 17, the wavelength conversion member 1750 may be disposed on a light emission surface of the light guiding plate 1740.

The wavelength conversion member 1650 or 1750, used in the example embodiments, may include green and red phosphors satisfying the conditions of a peak wavelength and a full width at half maximum, similar to the wavelength conversion member 150 described in FIG. 1.

FIG. 18 is a schematic exploded perspective view of a display apparatus according to an example embodiment.

With reference to FIG. 18, a display apparatus 2000 may include a backlight unit 2200, an optical sheet 2300, and an image display panel 2400 such as a liquid crystal panel.

The backlight unit 2200 may include a bottom case 2210, a reflective plate 2220, a light guiding plate 2240, and a light source module 2230 provided on at least one side of the light guiding plate 2240. The light source module 2230 may include a printed circuit board 2001 and white light emitting devices 2005, and may include the light source module 500 or 600 illustrated in FIG. 12 or FIG. 13. In an alternative embodiment, the white light emitting devices 2005 may include the white light emitting device 100 or 100a, illustrated in FIGS. 1 and 12, respectively. For example, the white light emitting devices 2005 may include side view-type light emitting devices having a side surface mounted to be adjacent to a light emission surface. In addition, in an example embodiment, the backlight unit 2200 may be replaced by any one of the backlight units 1200, 1500, 1600, or 1700, illustrated in FIGS. 14 through 17, respectively.

The optical sheets 2300 may be disposed between the light guiding plate 2240 and the image display panel 2400, and may include various types of sheets such as a diffusion sheet, a prism sheet, and/or a protective sheet.

The image display panel 2400 may display an image using light emitted through the optical sheets 2300. The image display panel 2400 may include an array substrate 2420, a liquid crystal layer 2430, and a color filter substrate 2440. The array substrate 2420 may include pixel electrodes disposed in a matrix form, thin film transistors that applies a driving voltage to the pixel electrodes, and signal lines that allow for operation of the thin film transistors. The color filter substrate 2440 may include a transparent substrate, a color filter, and a common electrode. The color filter may include filters that allow a specific wavelength of light to pass therethrough among white light emitted by the backlight unit 2200. The liquid crystal layer 2430 may be re-arranged by an electric field formed between the pixel electrodes and the common electrode to adjust a light transmitting rate. Light of which a light transmitting rate has been adjusted may pass through the color filter of the color filter substrate 2440 to thereby display an image. The image display panel 2400 may further include a driving circuit unit that processes an image signal and the like.

According to the display apparatus 2000 in the example embodiment, a color reproduction range implemented by light that passes through the color filter may be substantially increased. A color reproduction range of the display apparatus may cover 80% or more of the BT.2020 region in the CIE 1931 color space chromaticity diagram, and may also cover 100% or more based on the NTSC region.

As set forth above, according to example embodiments, a white light emitting device obtained by combining a blue LED with a green phosphor and a red phosphor, satisfying a full width at half maximum and a peak wavelength described above, may lead to implementing UHD TV-level color. In the case of using a color filter, a display apparatus implementing a color reproduction range of 80% or more, based on BT.2020, and 100% or more, based on NTSC, in the CIE 1931 color space chromaticity diagram may be provided.

While example embodiments have been shown and described above, it will be apparent to those skilled in the art that modifications and variations could be made without departing from the scope of the disclosure as defined by the appended claims.

What is claimed is:

1. A white light emitting device comprising:
a blue light emitting diode (LED) configured to emit light having a dominant wavelength in a range of 440 nm to 450 nm;
a green phosphor configured to convert at least a first portion of the light emitted by the blue LED to light having a peak wavelength in a range of 510 nm to 535 nm and having a full width at a half maximum of 35 nm or less; and
a red phosphor configured to convert at least a second portion of the light emitted by the blue LED to light having a peak wavelength in a range of 610 nm to 635 nm and having a full width at a half maximum of 30 nm or less.

2. The white light emitting device of claim 1, wherein the green phosphor has a peak wavelength in a range of 510 nm to 520 nm.

3. The white light emitting device of claim 1, wherein the red phosphor has a full width at a half maximum of 10 nm or less.

4. The white light emitting device of claim 1, wherein a color reproduction range of the white light emitting device covers 80% or more of a BT.2020 region in a CIE 1931 color space chromaticity diagram.

5. The white light emitting device of claim 1, wherein the green phosphor comprises at least one selected from a group consisting of BaMgAl₁₀O₁₇:Mn²⁺, BaMgAl₁₀O₁₇:Eu²⁺,Mn²⁺, BaMg_{1.5}Al_{10.5}O_{18.25}:Eu²⁺,Mn²⁺, BaMg_{1.5}Al_{10.5}O_{18.25}:Eu²⁺, Ba_{0.62}Mg_{0.67}Al_{10.33}O_{18.18}:Eu²⁺,Mn²⁺, BaMg₃Al₁₄O₂₁:Eu²⁺,Mn²⁺, KAlSi₂O₆:Mn²⁺, LaMgAl₁₂O₁₈:Mn²⁺, LaMgAl₁₂O₁₈:Eu²⁺,Mn²⁺, LaAl₁₁O₁₉:Mn²⁺, LaAl₁₁O₁₉:Mn²⁺,Eu²⁺, BA(Eu,Ce,Mg,La)Al₁₁O₁₆N, Ba_{0.95}Al₁₁O_{16.31}N_{0.76}:Eu²⁺,Mn²⁺, MgAl₃N₅:Eu²⁺,Mn²⁺, Mg_{0.2}Al_{1.45}O_{2.15}N_{0.75}:Eu²⁺,Mn²⁺, MgAl₂Si₁₀N₁₄:Eu²⁺,Mn²⁺, Sr₂Al₆O₁₁:Eu²⁺,Mn²⁺, Sr₂MgAl₆O₁₂:Eu²⁺,Mn²⁺, Sr₄Al₁₄O₂₅:Eu²⁺,Mn²⁺, Sr₄Mg₂Al₁₄O₂₇:Eu²⁺,Mn²⁺, Ca₈Mg(SiO₄)₄C₁₂:Eu²⁺,Mn²⁺, and Ca₃SiO₄C₁₂:Eu²⁺,Mn²⁺.

6. The white light emitting device of claim 1, wherein the red phosphor comprises a phosphor represented by at least one selected from:
a formula AₓMF_{y}:Mn⁴⁺, where A is at least one selected from lithium (Li), sodium (Na), kalium (K), rubidium (Rb), and caesium (Cs), M is at least one selected from silicon (Si), titanium (Ti), zirconium (Zr), hafnium (Hf), germanium (Ge), and tin (Sn), and 2≦x≦3 and 4≦y≦7,
a formula SrₓMg_{y}Si_{z}N_{2/3(x+y+2z+w)}:Eu_{w}, where 0.5≦x≦2, 2.5≦y≦3.5, 0.5≦z≦1.5, and 0≦w≦0.1, and
a formula M[LiₓAl_{y}N_{z}]:Eu_{2+W}, where M is at least one selected from calcium (Ca), strontium (Sr), barium (Ba), europium (Eu), and magnesium (Mg) and 0.1≦x≦1.2, 0.1≦y≦3.5, 0.1≦z≦4.5, and 0<w≦0.1.

7. The white light emitting device of claim 6, wherein the red phosphor comprises a fluoride particle represented by the formula AₓMF_{y}:Mn⁴⁺, and
a concentration of Mn⁴⁺ in the fluoride particle gradually decreases from a center portion to a surface portion of the fluoride particle.

8. The white light emitting device of claim 6, wherein the red phosphor comprises a fluoride particle represented by the formula AₓMF_{y}:Mn⁴⁺, and
an organic material is physically absorbed onto the fluoride particle to allow the fluoride particle to have a hydrophobic property.

9. The white light emitting device of claim 1, wherein the green phosphor comprises at least one of BaMgAl₁₀O₁₇:Mn²⁺, BaMgAl₁₀O₁₇:Eu²⁺,Mn²⁺, and LaMgAl₁₂O₁₈:Eu²⁺,Mn²⁺, and the red phosphor comprises K₂SiF₆:Mn⁴⁺.

10. The white light emitting device of claim 1, further comprising a near ultraviolet LED configured to emit light having a dominant wavelength in a range of 360 nm to 420 nm.

11. A display apparatus comprising:
an image display panel comprising a color filter layer, the color filter layer comprising red, green, and blue color filters;
a light source unit comprising a plurality of blue light emitting diodes (LEDs) that emit light; and
a wavelength conversion member comprising:
a green phosphor configured to convert at least a first portion of light emitted by a blue LED to light having a peak wavelength in a range of 510 nm to 535 nm and having a full width at a half maximum of 35 nm or less, and
a red phosphor configured to convert at least a second portion of the light emitted by the blue LED to light having a peak wavelength in a range of 610 nm to 635 nm and having a full width at a half maximum of 30 nm or less.

12. The display apparatus of claim 11, wherein the green phosphor has a peak wavelength in a range of 510 nm to 520 nm, and the red phosphor has a full width at a half maximum of 10 nm or less.

13. The display apparatus of claim 11, wherein a color reproduction range of the display apparatus covers 80% or more of a BT.2020 region in a CIE 1931 color space chromaticity diagram.

14. The display apparatus of claim 11, wherein the green phosphor comprises at least one of phosphors represented by BaMgAl₁₀O₁₇:Eu²⁺,Mn²⁺ and LaMgAl₁₂O₁₈:Mn²⁺, and the red phosphor comprises a fluoride phosphor represented by AₓMF_{y}:Mn⁴⁺, where A is at least one selected from Li, Na, K, Rb, and Cs, M is at least one selected from Si, Ti, Zr, Hf, Ge, and Sn, and 2≦x≦3 and 4≦y≦7.

15. The display apparatus of claim 11, wherein the light source unit comprises a light guide plate, and the wavelength conversion member is provided on the light guide plate.

16. A white light emitting device comprising:
a blue light emitting diode (LED) configured to emit light having a dominant wavelength in a range of 440 nm to 450 nm;
a wavelength-conversion member configured to convert at least a portion of light emitted from the blue LED into red light, the wavelength-conversion member comprising a red phosphor represented by at least one from:
a formula AₓMF_{y}:Mn⁴⁺, where A is at least one selected from Li, Na, K, Rb, and Cs, M is at least one selected from Si, Ti, Zr, Hf, Ge, and Sn, and 2≦x≦3 and 4≦y≦7,
a formula SrₓMg_{y}Si_{z}N_{2/3(x+y+2z+w)}:Eu_{w}, where 0.5≦x≦2, 2.5≦y≦3.5, 0.5≦z≦1.5, and 0<w≦0.1, and
a formula M[LiₓAl_{y}N_{z}]:Eu_{2+W}, where M is at least one selected from Ca, Sr, Ba, Eu, and Mg and 0.1≦x≦1.2, 0.1≦y≦3.5, 0.1≦z≦4.5, and 0<w≦0.1; and
a second wavelength-conversion member configured to convert at least a second portion of the light emitted from the blue LED into green light,
wherein the green light converted by the second wavelength-conversion member has a peak wavelength in a range of 510 nm to 535 nm and has a full width at a half maximum of 35 nm or less.

17. The white light emitting device of claim 16, wherein the red light converted by the wavelength-conversion member has a peak wavelength in a range of 610 nm to 635 nm and has a full width at a half maximum of 30 nm or less.

18. The white light emitting device of claim 16, wherein the red phosphor is represented by the formula AₓMF_{y}:Mn⁴⁺, and
a concentration of Mn⁴⁺ in the red phosphor gradually decreases from a center portion to a surface portion of the red phosphor.

19. The white light emitting device of claim 16, wherein the green phosphor comprises at least one selected from a group consisting of BaMgAl₁₀O₁₇:Mn²⁺, BaMgAl₁₀O₁₇:Eu²⁺,Mn²⁺, BaMg_{1.5}Al_{10.5}O_{18.25}:Eu²⁺,Mn²⁺, BaMg_{1.5}Al_{10.5}O_{18.25}:Eu²⁺, Ba_{0.62}Mg_{0.67}Al_{10.33}O_{18.18}:Eu²⁺,Mn²⁺, BaMg₃Al₁₄O₂₁:Eu²⁺,Mn²⁺, KAlSi₂O₆:Mn²⁺, LaMgAl₁₂O₁₈:Mn²⁺, LaMgAl₁₂O₁₈:Eu²⁺,Mn²⁺, LaAl₁₁O₁₉:Mn²⁺, LaAl₁₁O₁₉:Mn²⁺,Eu²⁺, BA(Eu,Ce,Mg,La)Al₁₁O₁₆N, Ba_{0.95}Al₁₁O_{16.31}N_{0.76}:Eu²⁺,Mn²⁺, MgAl₃N₅:Eu²⁺,Mn²⁺, Mg_{0.2}Al_{1.45}O_{2.15}N_{0.75}:Eu²⁺,Mn¹²⁺, MgAl₂Si₁₀N₁₄:Eu²⁺,Mn²⁺, Sr₂Al₆O₁₁:Eu²⁺,Mn²⁺, Sr₂MgAl₆O₁₂:Eu²⁺,Mn²⁺, Sr₄Al₁₄O₂₅:Eu²⁺,Mn²⁺, Sr₄Mg₂Al₁₄O₂₇:Eu²⁺,Mn²⁺, Ca₈Mg(SiO₄)₄C₁₂:Eu²⁺,Mn²⁺, and Ca₃SiO₄C₁₂:Eu²⁺,Mn²⁺.
